(19) United States
(12) Patent Application Publication
(10) Pub. No.: US 2018/0138875 A1
(43) Pub. Date: May 17, 2018

(54) AUDIO EQUIPMENT AND ELECTRONIC DEVICE THEREOF

(71) Applicants: INVENTEC (PUDONG) TECHNOLOGY CORPORATION, Shanghai City (CN); INVENTEC CORPORATION, Taipei City (TW)

(72) Inventors: Kun-Hui LAI, Taipei City (TW); Feng-Sheng KUAN, Taipei City (TW); Ting-Chang KUO, Taipei City (TW); Pei-Lien WANG, Taipei City (TW)

(73) Assignees: INVENTEC (PUDONG) TECHNOLOGY CORPORATION, Shanghai City (CN); INVENTEC CORPORATION, Taipei City (TW)

(21) Appl. No.: 15/479,024

(22) Filed: Apr. 4, 2017

(30) Foreign Application Priority Data
Nov. 17, 2016 (CN) 201611022146.1

(51) Int. Cl. H03G 3/10; G10L 19/00; H04R 3/00

(52) U.S. Cl. CPC H03G 3/10; H04R 3/00; G10L 19/00

(57) ABSTRACT

An electronic device includes a case, an electronic assembly, a rotary member and a positioning module. The case includes a bottom plate and a side plate. The electronic assembly includes a circuit board and an electronic component. The electronic component is fastened to the circuit board. The circuit board is disposed on the bottom plate. The rotary member is disposed through the side plate and an assembling hole of the electronic component in sequence. The positioning module is fastened to the bottom plate, and the positioning module is disposed through the circuit board of the electronic assembly. The positioning module has a blocking surface facing the bottom plate. A part of the circuit board is located between the blocking surface and the bottom plate, and a distance between the blocking surface and the bottom plate is larger than a thickness of the circuit board.

### CROSS-REFERENCE TO RELATED APPLICATIONS

This non-provisional application claims priority under 35 U.S.C. § 119(a) on Patent Application No(s). 201611022146.1 filed in China on Nov. 17, 2016, the entire contents of which are hereby incorporated by reference.

### TECHNICAL FIELD

The disclosure relates to an audio equipment and an electronic device, more particularly to an electronic device including an encoder, and an audio equipment including the electronic device.

### BACKGROUND

Generally, there are lots of electronic components disposed in one electronic device. For person skilled in the art, it is important to confirm whether some of the delicate electronic components in the electronic device are fixed in place. Said delicate electronic component is, for example, an encoder. The encoder is a transducer, software program or algorithm that converts information from one format or code to another, for the purposes of standardization, security, confidentiality, speed or compressions. According to the calibration method and the signal output, the encoder can be divided into absolute type and incremental type. The incremental typed encoder is applicable to volume control and menu selection.

### SUMMARY

According to one aspect of the disclosure, an electronic device includes a case, an electronic assembly, a rotary member and a positioning module. The case includes a bottom plate and a side plate connected to each other. The electronic assembly includes a circuit board and an electronic component. The electronic component is fastened to the circuit board. The circuit board is disposed in the case, and the circuit board is disposed on the bottom plate. The rotary member is disposed through the side plate and an assembling hole of the electronic component in sequence. The positioning module is disposed in the case. The positioning module is fastened to the bottom plate, and the positioning module is disposed through the circuit board of the electronic assembly. The positioning module has a blocking surface facing the bottom plate. A part of the circuit board is located between the blocking surface and the bottom plate, and a distance between the blocking surface and the bottom plate is larger than a thickness of the circuit board.

According to one aspect of the disclosure, an electronic device includes a case, a circuit board and a positioning module. The circuit board is disposed in the case. The positioning module is disposed in the case. The positioning module is fastened to the case, and the positioning module is disposed through the circuit board of the electronic assembly. The positioning module has a blocking surface facing the case. A part of the circuit board located between the blocking surface and the case, and a distance between the blocking surface and the case is larger than a thickness of the circuit board.

According to one aspect of the disclosure, an audio equipment includes one of the aforementioned electronic devices.

### BRIEF DESCRIPTION OF THE DRAWINGS

The present disclosure will become better understood from the detailed description given hereinbelow and the accompanying drawings which are given by way of illustration only and thus are not limitative of the present disclosure and wherein:

FIG. 1A is a perspective view of an electronic device according to a first embodiment;

FIG. 1B is a cross sectional view of the electronic device in FIG. 1A;

FIG. 1C and FIG. 1D are cross sectional views of the electronic device in FIG. 1B, when a rotary member is disposed through an encoder;

FIG. 2A and FIG. 2B are cross sectional views of the electronic device according to a second embodiment, when a rotary member is disposed through an encoder; and

FIG. 3 is a perspective view of an audio equipment according to a third embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

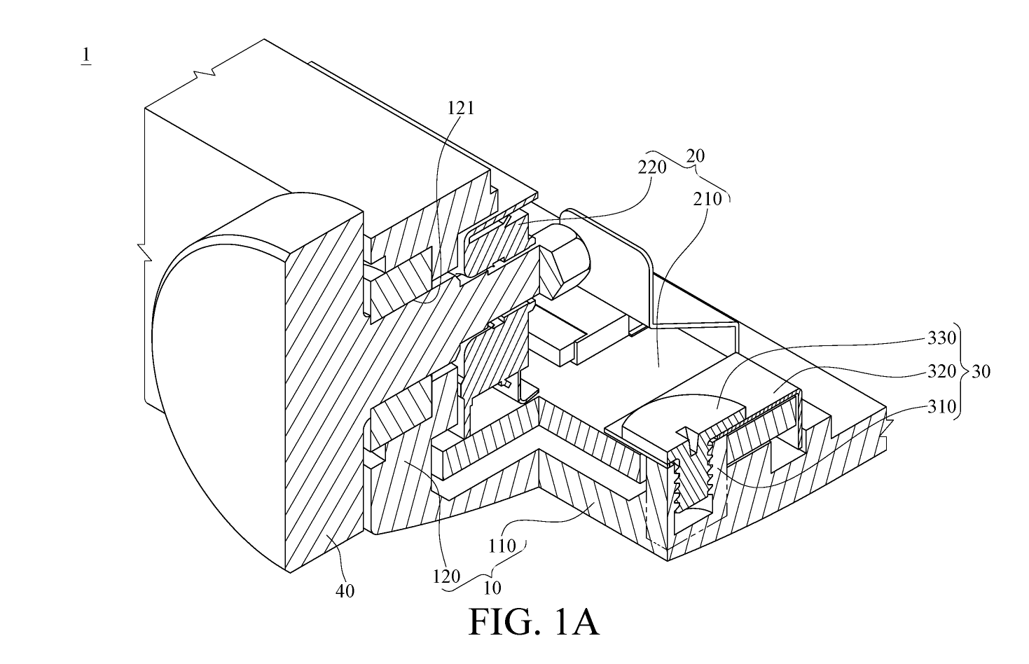

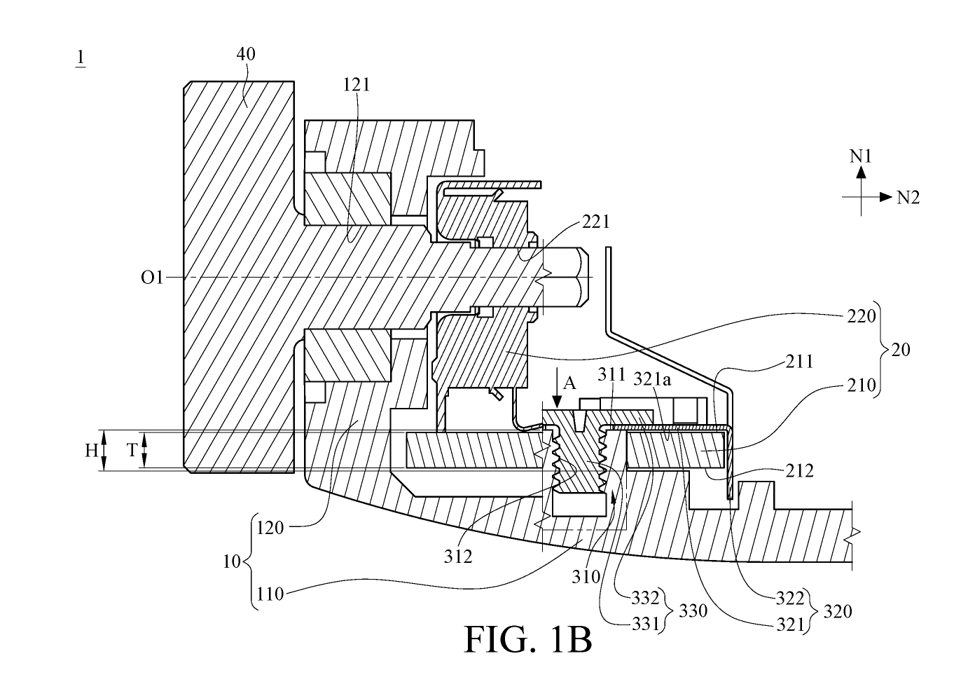

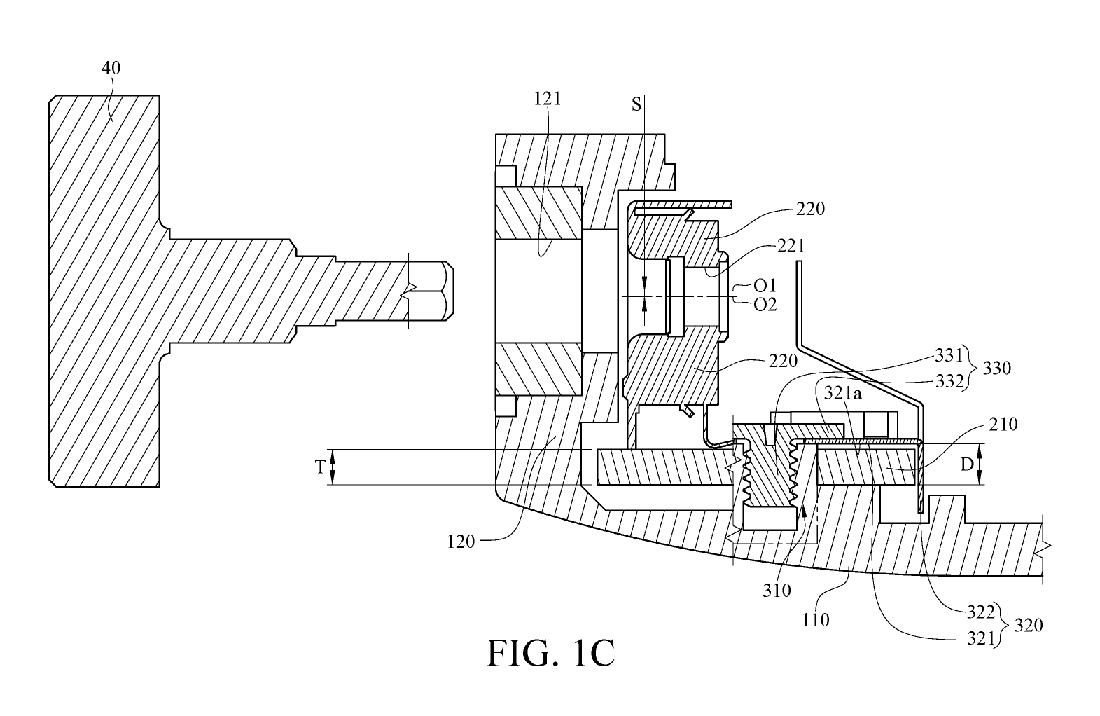

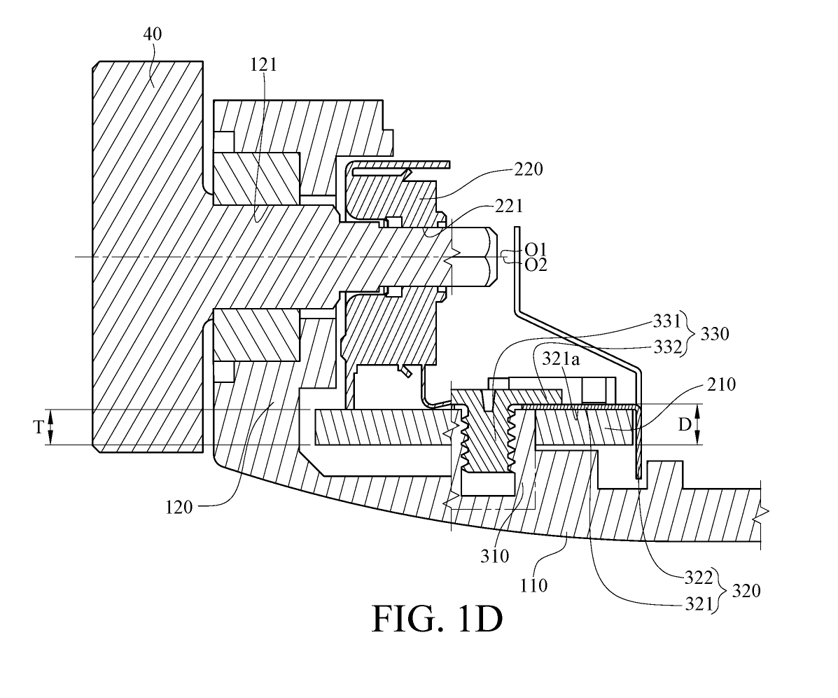

Please refer to FIG. 1A and FIG. 1B. FIG. 1A is a perspective view of an electronic device according to a first embodiment. FIG. 1B is a cross sectional view of the electronic device in FIG. 1A. In this embodiment, the electronic device 1 includes a case 10, an electronic assembly 20, a positioning module 30 and a rotary member 40.

The case 10 includes a bottom plate 110 and a side plate 120 connected to each other. The side plate 120 is located on a side of the bottom plate 110, and the side plate 120 has an opening 121. In this embodiment, a normal direction N1 of the bottom plate 110 is substantially orthogonal to a normal direction N2 of the side plate 120.

The electronic assembly 20 is disposed in the case 10, and the electronic assembly 20 includes a circuit board 210 and an electronic component 220. The electronic component 220 is fastened to the circuit board 210. For example, in this embodiment, the electronic component 220 has a plurality of pins which are inserted into or welded to metal pads on the circuit board 210. The electronic component 220 is, for example but not limited to, an encoder. The circuit board 210 has a top surface 211 and a bottom surface 212 opposite to each other, and the bottom surface 212 faces the bottom plate 110 of the case 10. Furthermore, the electronic component 220 has an assembling hole 221.

The positioning module 30 is disposed in the case 10, and the positioning module 30 is fastened to the bottom plate 110. The positioning module 30 is disposed through the circuit board 210. In detail, the positioning module 30 includes a protrusion 310, a blocking member 320 and a fastener 330.

The protrusion 310 is fastened to the bottom plate 110, and the protrusion 310 has a top surface 311 and a fastening hole 312 located on the top surface 311. The protrusion 310 protrudes from the bottom plate 110 at a height H. The circuit board 210 is disposed on the bottom plate 110 of the case 10, and the protrusion 310 is disposed through the circuit board 210. The height H is larger than a thickness T of the circuit board 210. In this embodiment, the protrusion 310 and the bottom plate 110 of the case 10 are integral with each other, but the disclosure is not limited thereto. In some embodiments, the protrusion and the bottom plate are two independent objects, and the protrusion is, for example, adhered to or screwed to the bottom plate.

The blocking member 320 is disposed in the case 10, and a part of the circuit board 210 of the electronic assembly 20 is located between the bottom plate 110 of the case 10 and the blocking member 320. In detail, the blocking member 320 includes a blocking portion 321 and a limiting portion 322 connected to each other. The blocking portion 321 of the positioning module 30 has a blocking surface 321a, and the blocking surface 321a faces the bottom plate 110. The circuit board 210 is disposed between the blocking surface 321a and the bottom plate 110, and the top surface 211 of the circuit board 210 faces the blocking portion 321. The blocking portion 321 is disposed on the top surface 311 of the protrusion 310. The limiting portion 322 extends from a side of the blocking portion 321 toward the bottom plate 110 of the case 10, and the limiting portion 322 is located on a side of the circuit board 210. In this embodiment, the blocking member 320 includes the blocking portion 321 and the limiting portion 322, but the disclosure is not limited thereto. In some embodiments, the blocking member may have no limiting portion.

When the fastener 330 is moved toward the circuit board 210 in a fastening direction A so as to be fastened to the case 10, the blocking member 320 is fastened to the case 10 by the fastener 330. In detail, the fastener 330 is, for example, but not limited to, a screw including a main body 331 and a pressing part 332. The pressing part 332 is located around and protrudes from the main body 331. The main body 331 is disposed through the blocking portion 321 of the blocking member 320 in the fastening direction A. The main body 331 is screwed into the fastening hole 312 on the top surface 311 of the protrusion 310 so as to be fastened to the bottom plate 110. The blocking member 320 is fastened to the bottom plate 110 by the fastener 330. In this embodiment, when the main body 331 of the fastener 330 is screwed into the fastening hole 312, the pressing part 332 directly contacts the blocking portion 321 of the blocking member 320, and the blocking portion 321 directly contacts the top surface 311 of the protrusion 310; thereby, the blocking portion 321 of the blocking member 320 is sandwiched between the pressing part 332 and the protrusion 310. In this embodiment, the blocking member 320 and the fastener 330 are two independent objects in order to reduce manufacturing cost, but the disclosure is not limited thereto. In some embodiments, the blocking member and the fastener are integral with each other; for example, the pressing part of the fastener further protrudes from the main body to have a relatively large width in horizontal direction, such that the pressing part has sufficient bottom area to be taken as a blocking surface.

According to the configuration of the electronic device 1 described above, the circuit board 210 of the electronic assembly 20 is movable relative to the case 10 in an axial direction of the main body 331 of the fastener 330, such that the location of the circuit board 210 between the blocking surface 321a of the blocking portion 321 and the bottom plate 110 in the vertical direction is adjustable, from the point of view in FIG. 1C. The detail description about the interaction among the members of the electronic device 1 is described in the following paragraphs.

The rotary member 40 is, for example, but not limited to, a volume knob. The rotary member 40 is disposed through the opening 121 of the side plate of the case 10 and the assembling hole 221 of the electronic component 220 in sequence. The rotary member 40 is rotatable relative to the electronic component 220 and the case 10 with its axis O1 as the center of rotation.

The technical means of the electronic device 1 for solving assembly problem in traditional electronic device are described in the following paragraphs.

As shown in FIG. 1B, when there is no manufacturing tolerance on the circuit board 210, or the electronic component 220, or there is a slight manufacturing tolerance (e.g. negligible manufacturing tolerance) thereon, the center of the assembling hole 221 is aligned with the axis O1 of the rotary member 40. In such a case, the rotary member 40 is able to be smoothly inserted into the assembling hole 221 so as to accomplish the assembly of the rotary member 40 and the electronic component 220.

Then, the situation in which there is a significant manufacturing tolerance on the circuit board 210 or the electronic component 220 is described in the following paragraphs.

Please refer to FIG. 1C and FIG. 1D. FIG. 1C and FIG. 1D are cross sectional views of the electronic device in FIG. 1B, when a rotary member is disposed through the encoder. As shown in FIG. 1C, there is a significant manufacturing tolerance on the electronic component 220. Since the electronic component 220 has manufacturing tolerance, there is a deviation S in the vertical direction between the center O2 of the assembling hole 221 and the axis O1 of the rotary member 40. According to the known manufacturing techniques, the deviation S is able to be reduced to less than 0.2 millimeters (mm). Generally, the deviation S is about 0.1 mm.

Since the deviation S is existed between the assembling hole 221 and the rotary member 40, a side surface of the electronic component 220 or an inner surface in the assembling hole 221 is pressed against the rotary member 40, when the rotary member 40 passes into the assembling hole 221 of the electronic component 220. The interference between the rotary member 40 and the electronic component 220 generates an upward force. As shown in FIG. 1D, the upward force forces the circuit board 210 to move upward in the axial direction of the main body 331 of the fastener 330, such that the axis O1 of the rotary member 40 is aligned with the center O2 of the assembling hole 221. Thus, the deviation S is eliminated, such that the rotary member 40 is able to be smoothly inserted into the assembling hole 221 so as to accomplish the assembly of the rotary member 40 and the electronic component 220.

In this embodiment, the blocking member 320 is favorable for restricting the movement of the circuit board 210. In detail, when the circuit board 210 is moved upward, the blocking portion 321 is configured to stop the movement of the circuit board 210, such that the movement of the circuit board 210 in the vertical direction is restricted between the blocking portion 321 and the bottom plate 110 of the case 10. Furthermore, since the circuit board 210 is not fastened to the case 10, the circuit board 210 is movable relative to the bottom plate 110 in a horizontal direction. The movement of the circuit board 210 in the horizontal direction is restricted between the limiting portion 322 and the side plate 120 of the case 10.

As shown in FIG. 1C and FIG. 1D, according to the known manufacturing techniques, a distance D between the blocking surface 321a of the positioning module 30 and the bottom plate 110 minus the thickness T of the circuit board 210 is greater than or equal to 0.40 mm in this embodiment, such that it is favorable for the circuit board 210 having proper mobility while positioning the circuit board 210 at a proper location. When the distance D minus the thickness T is less than 0.40 mm, the mobility of the circuit board 210 is overly restricted so as to be unfavorable to compensate for the manufacturing tolerance. In some embodiments, considering an average value of the manufacturing tolerance, the distance D minus the thickness T is less than 0.20 mm.

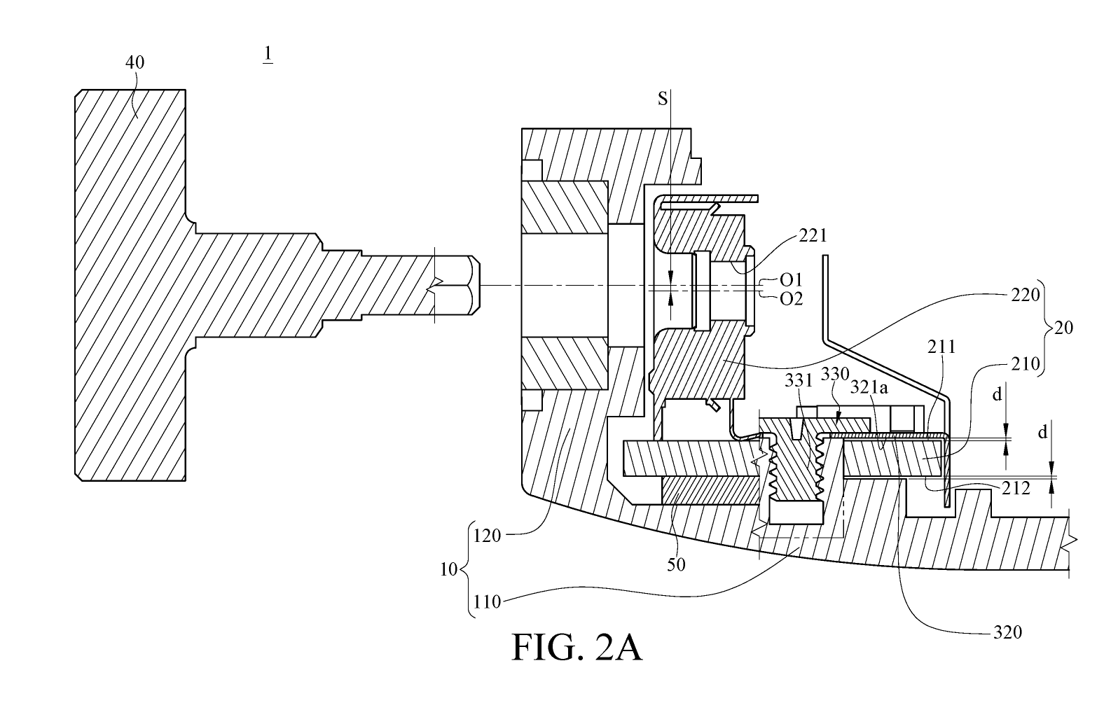

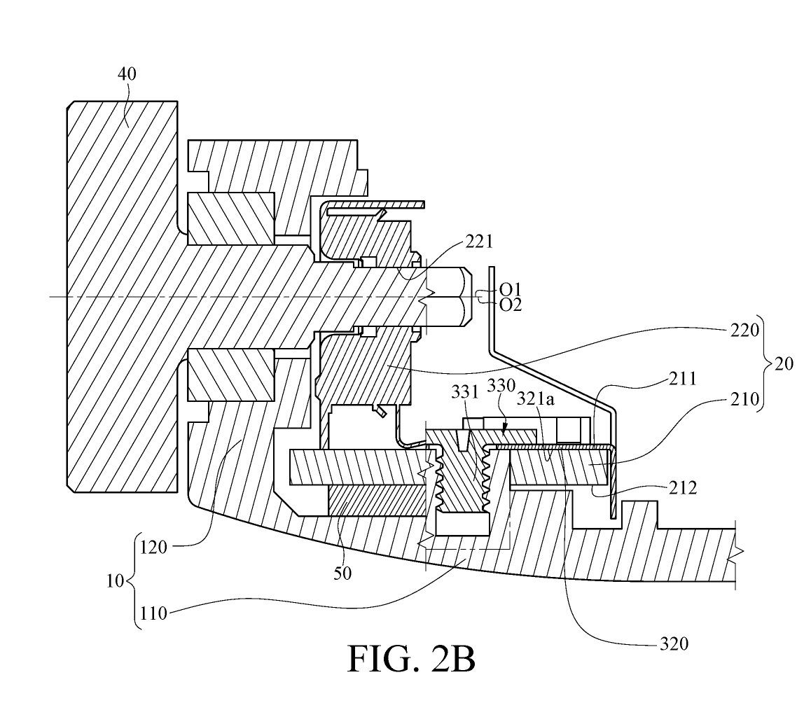

The following describes another configuration of the electronic device. Please refer to FIG. 2A and FIG. 2B. FIG. 2A and FIG. 2B are cross sectional views of the electronic device according to a second embodiment, when a rotary member is disposed through the encoder. Since the second embodiment is similar to the first embodiment, only the difference will be illustrated. In this embodiment, the electronic device 1 further includes an electrically conductive foam 50.

The electrically conductive foam 50 is disposed between the circuit board 210 of the electronic assembly 20 and the bottom plate 110 of the case 10. In this embodiment, the electrically conductive foam 50 is adhered to the bottom surface 212 of the circuit board 210. The electrically conductive foam 50 is favorable for reducing electromagnetic interference and determining the location of the circuit board 210 in the vertical direction. In detail, a thickness of the electrically conductive foam 50 is able to be thicker to slightly lift up the circuit board 210 from the bottom plate 110 of the case 10. Thus, before the electronic component 220 is assembled with the rotary member 40, there is a distance D between the top surface 211 of the circuit board 210 and the blocking surface 321a of the blocking member 320, while there is also a distance D between the bottom surface 212 and the bottom plate 110. When there is a deviation S between the center O2 of the assembling hole 221 of the electronic component 220 and the axis O1 of the rotary member 40 in the vertical direction, whether the center O2 of the assembling hole 221 is higher than or lower than the axis O1 of the rotary member 40, the circuit board 210 is able to be moved upward or downward in the axial direction of the main body 331 of the fastener 330, such that the axis O1 of the rotary member 40 is aligned with the center O2 of the assembling hole 221. In this embodiment, the distance D is 0.2 mm. In some embodiments, the distance D is 0.10 mm.

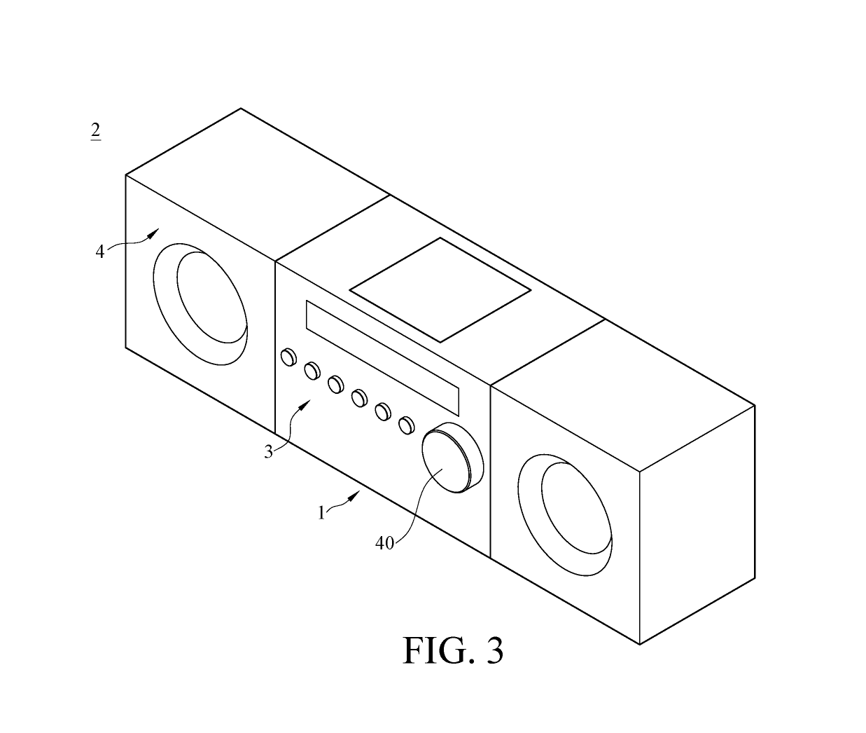

The aforementioned electronic devices are applicable to an audio equipment. Please refer to FIG. 3. FIG. 3 is a perspective view of an audio equipment according to a third embodiment. In this embodiment, the audio equipment 2 include the electronic device 1 disclosed in one of the aforementioned embodiments, a control panel 3 and a speaker 4. The rotary member 40 in the electronic device 1 is a rotary volume knob, and a head of the rotary volume knob is exposed to outside.

According to the disclosure, the configuration of the electronic device, in which the circuit board is not fastened to the case by the positioning module, is different from the configuration of the conventional electronic device, in which the circuit board is fastened to the case by the positioning module. Furthermore, the distance between the blocking surface of the positioning module and the bottom plate of the case is larger than the thickness of the circuit board. Therefore, after the circuit board is assembled with the case and the positioning module, the circuit board is movably disposed in the case; before the rotary member is assembled with the electronic component, the circuit board is movable relative to the case between the blocking surface and the bottom plate. When the rotary member is disposed through the hole of the electronic component, the rotary member applies a force on the electronic component so as to move the circuit board upward or downward, thereby the center of the hole is aligned with the axis of the rotary member. Accordingly, when there is a manufacturing tolerance on the circuit board or the electronic component, the location of the circuit board is adjustable to compensate for the manufacturing tolerance, such that the rotary member is well assembled with the electronic component.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. An electronic device, comprising:
a case comprising a bottom plate and a side plate connected to each other;
an electronic assembly comprising a circuit board and an electronic component, the electronic component fastened to the circuit board, the circuit board disposed in the case, and the circuit board disposed on the bottom plate;
a rotary member disposed through the side plate and an assembling hole of the electronic component in sequence; and
a positioning module disposed in the case, the positioning module fastened to the bottom plate, the positioning module disposed through the circuit board of the electronic assembly, the positioning module having a blocking surface facing the bottom plate, a part of the circuit board located between the blocking surface and the bottom plate, and a distance between the blocking surface and the bottom plate being larger than a thickness of the circuit board.

2. The electronic device according to claim 1, wherein the electronic component is an encoder, and the rotary member is a volume knob.

3. The electronic device according to claim 1, wherein the distance between the blocking surface and the bottom plate minus the thickness of the circuit board is greater than or equal to 0.4 millimeters.

4. The electronic device according to claim 1, wherein a normal direction of the bottom plate is substantially orthogonal to a normal direction of the side plate.

5. The electronic device according to claim 1, wherein the positioning module comprises a fastener and a blocking member, the fastener and the blocking member are independent object, the fastener is fastened to the bottom plate of the case, the blocking member is fastened to the bottom plate by the fastener, and the blocking member has the blocking surface.

6. The electronic device according to claim 5, wherein the positioning module further comprises a protrusion, the protrusion protrudes from the bottom plate at a height which is larger than the thickness of the circuit board, the protrusion has a top surface and a fastening hole located on the top surface, the protrusion is disposed through the circuit board, the fastener comprises a main body and a pressing part, the pressing part located around and protrudes from the main body, the main body is screwed to the fastening hole, the pressing part directly contacts the blocking member, the blocking member directly contacts the top surface of the protrusion, and the blocking member is sandwiched between the pressing part of the fastener and the protrusion.

7. The electronic device according to claim 5, wherein the blocking member comprises a blocking portion and a limiting portion connected to each other, the blocking portion has the blocking surface, the limiting portion extends from a side of the blocking portion toward the case, and the limiting portion is located on a side of the circuit board of the electronic assembly.

8. The electronic device according to claim 1, further comprising an electrically conductive foam disposed between the circuit board of the electronic assembly and the bottom plate.

9. An electronic device, comprising:
a case;
a circuit board disposed in the case; and
a positioning module disposed in the case, the positioning module fastened to the case, the positioning module disposed through the circuit board of the electronic assembly, the positioning module having a blocking surface facing the case, a part of the circuit board located between the blocking surface and the case, and a distance between the blocking surface and the case being larger than a thickness of the circuit board.

10. An audio equipment, comprising:
the electronic device according to claim 1.
